(19) United States
(12) Patent Application Publication
(10) Pub. No.: US 2021/0232723 A1
(43) Pub. Date: Jul. 29, 2021

(54) NETWORK DESIGN EVALUATION METHOD, NETWORK DESIGN EVALUATION DEVICE, AND PROGRAM

(71) Applicant: NIPPON TELEGRAPH AND TELEPHONE CORPORATION, Tokyo (JP)

(72) Inventor: Takeru INOUE, Musashino-shi, Tokyo (JP)

(73) Assignee: NIPPON TELEGRAPH AND TELEPHONE CORPORATION, Tokyo (JP)

(21) Appl. No.: 16/973,756

(22) PCT Filed: Jun. 7, 2019
(86) PCT No.: PCT/JP2019/022764

§ 371 Date: Dec. 9, 2020

(30) Foreign Application Priority Data
Jun. 14, 2018 (JP) 2018-113884

(51) Int. Cl. G06F 30/18; G06F 30/20

(52) U.S. Cl. CPC G06F 30/18; G06F 30/20

(57) ABSTRACT

An object is to provide a network design evaluation method, a network design evaluation apparatus, and a program with the ZDD algorithm for finding all edge-disjoint paths in a given graph G within a finite time. A network design evaluation method according to the present invention includes extracting all paths for each specified pair of vertices in a given graph in the frontier-based search, representing a set of paths having, as elements, the paths extracted for each pair of vertices in a ZDD, and performing a disjoint join operation for all the sets of paths represented in ZDDs, to thereby extract edge-disjoint paths.

### TECHNICAL FIELD

The present disclosure relates to a network design evaluation technique, a network design evaluation apparatus, and a program, which find edge-disjoint paths in a network.

### BACKGROUND ART

In discrete mathematical programming, such as combinatorial optimization and constraint satisfaction problems, a zero-suppressed binary decision diagram (ZDD) has received attention (see, e.g., NPL1). In many of mathematical programming problems, to search for an optimal solution in a feasible region that satisfies constraints, a good representation method for constraints holds the key to computational efficiency. A ZDD is a data structure and an algorithm that provide a compact representation of constraints without excess and deficiency.

It is known that handling constraints by using a ZDD allows efficient execution of optimization and probability evaluation. For example, it is possible to select a feasible solution with the minimum cost from among those satisfying the constraints and also to evaluate a probability of a system to be not feasible. In recent years, constraints defined by using a network (NW) and a graph can be handled with a ZDD by a newly developed algorithm called frontier-based search (see, e.g., NPL2).

### CITATION LIST

### Non Patent Literature

NPL1: Takeshi Inoue, “Research Trends in ZDD and Frontier-based Search”, the journal of the Institute of Electronics, Information and Communication Engineers, vol. 101, no. 3, pp. 297-301, 2018.
NPL2: J. Kawahara, T. Inoue, H. Iwashita, and S. Minato, “Frontier-based search for enumerating all constrained subgraphs with compressed representation”, IEICE Transactions on Fundamentals of Electronics, Communications and Computer Sciences, vol. E100.A, no. 9, pp. 1773-1784, 2017.
NPL3: J. Kawahara, T. Saitoh, H. Suzuki, and R. Yoshinaka, “Solving the longest oneway-ticket problem and enumerating letter graphs by augmenting the two representative approaches with ZDDs”, in Computational Intelligence in Information Systems, 2017, pp. 294-305.

### SUMMARY OF THE INVENTION

### Technical Problem

The frontier-based search can handle major graph constraints such as paths and connectivity. However, constraints of edge-disjoint paths, which is a major concept described in most textbooks related to algorithms and optimization, could not be handled in the frontier-based search.

First, an edge-disjoint path will be described. A graph G=(V, E) and several pairs of vertices K={{u, v}, . . . }⊂V*V are given for a set of vertices V and a set of edges E. In the present invention, an undirected graph is considered. To satisfy the edge-disjoint path constraint, not only a path connecting the vertices of each of the pairs of vertices K are present, but also any of these paths must not pass the same edge (the paths may pass the same vertex). Depending on a graph and pairs of vertices edge-disjoint path may not exist, or may some patterns of edge-disj oint paths exists.

With a NW in FIG. 1 as an example, examples of an edge-disjoint path are illustrated in FIG. 2. The set of vertices V consists of five vertices (one in black, two in white, and two in gray). The set of edges E is as follows: E={e₁, e₂, e₃, e₄, e₅, e₆}. Connect vertices of each of the pairs of the vertices in the same color with a path so that the paths do not pass through the same edge. Although all the examples in FIG. 2(a) present edge-disjoint paths, the paths in the example in FIG. 2(b) are not edge-disjoint because the paths overlap at e₅.

The edge-disjoint constraint provides a fundamental concept representing basic concepts representing a resource conflict in a NW and forms the foundations of wavelength assignment, traffic engineering, and so on. However, to find all the edge-disjoint paths present in a NW, all the 2^{|E|} combinations of edges need to be examined, and this leads to a problem that the operation is not completed within a realistic time even in a case with a small graph with |E| of several tens.

To solve the above problems, an object of the present invention is to provide a network design evaluation method, a network design evaluation apparatus, and a program with the ZDD algorithm for finding all edge-disjoint paths in a given graph G within a finite time.

### Means for Solving the Problem

In order to achieve the above object, a network design evaluation method according to the present invention includes extracting all paths for each specified pair of vertices in a given graph in the frontier-based search, representing a set of paths having, as elements, the paths extracted for each pair of vertices in a ZDD, and performing a disjoint join operation for all the sets of paths represented in ZDDs, to thereby extract edge-disjoint paths.

Specifically, the network design evaluation method according to the present invention includes: a condition input step of giving, when a network is represented with vertices and edges, a graph and at least one pair of vertices, the graph consisting of a set of vertices and a set of edges, each of the pairs of vertices consisting of two vertices included in the set of vertices; a path set calculation step of calculating, for each of the pair of vertices given in the condition input step, a set of paths each connecting the two vertices with at least one edge included in the set of edges, in frontier-based search; and an edge-disjoint path extraction step of calculating a disjoint join for all the sets of paths calculated in the path set calculation step, to extract all edge-disjoint paths included in the graph given in the condition input step.

A network design evaluation apparatus according to the present invention includes: a storage unit configured to store a graph and at least one pair of vertices given for a network represented by vertices and edges, the graph consisting of a set of vertices and a set of edges, the pair of vertices consisting of two vertices included in the set of vertices; a path set calculation unit configured to calculate, for each of the pairs of vertices stored in the storage unit, a set of paths each connecting the two vertices with at least one edge included in the set of edges, in frontier-based search; and an edge-disjoint path extraction unit configured to calculate a disjoint join for all the sets of paths calculated by the path set calculation unit, to extract all edge-disjoint paths included in the graph stored in the storage unit.

In the present invention, instead of finding edge-disjoint paths one by one, a set of edges is found for each of the pairs of vertices in the frontier-based search first, and edge-disjoint paths are extracted through disjoint join operation for combinations with no common element. Because sets of edges can be found efficiently in the frontier-based search, all edge-disjoint paths in a NW can be found within a finite time. Hence, the present invention can provide a network design evaluation method, a network design evaluation apparatus, and a program with a ZDD algorithm for finding all edge-disjoint paths in a given graph G within a finite time.

A program according to the present invention is a program for causing a computer to execute the above-described network design evaluation method. The network design evaluation method can be executed with a computer and a program, and the program can be recorded in a recording medium or can be provided through a network.

### Effects of the Invention

The present invention can provide a network design evaluation method, a network design evaluation apparatus, and a program with a ZDD algorithm for finding all edge-disjoint paths in a given graph G within a finite time.

### BRIEF DESCRIPTION OF DRAWINGS

FIG. 1 is an example of a network represented with vertices and edges.

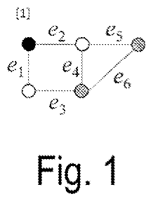

FIG. 2 is a diagram illustrating examples of an edge-disjoint path. FIG. 2(a) illustrates examples of an edge-disjoint path, and FIG. 2(b) illustrates an example that is not an edge-disjoint path.

FIG. 3 is a diagram illustrating sets of paths searched out in the frontier-based search. FIG. 3(a) illustrates a set of paths connecting white vertices, and FIG. 3(b) illustrates a set of paths connecting gray vertices.

FIG. 4 is a diagram illustrating sets of paths represented in ZDDs. FIG. 4(a) illustrates a ZDD representing Π_{white}, and FIG. 4(b) illustrates a ZDD representing Π_{gray}.

FIG. 5 is a diagram in which all edge-disjoint paths are represented in a ZDD.

FIG. 6 is a flowchart illustrating a network design evaluation method according to the present invention.

FIG. 7 is a block diagram illustrating a network design evaluation apparatus according to the present invention.

### DESCRIPTION OF EMBODIMENTS

An embodiment of the present invention will be described with reference to the drawings. The embodiment to be described below is an example of the present invention. The present invention is not limited to the following embodiment. Note that, in this specification and the drawings, constituent elements having the same reference signs are assumed to be the same.

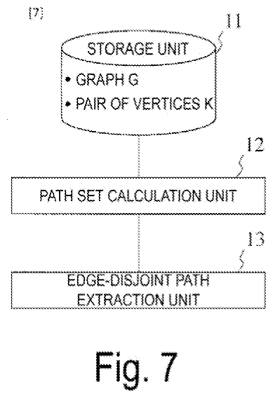

FIG. 7 is a block diagram illustrating a network design evaluation apparatus according to the present embodiment. The present network design evaluation apparatus includes a storage unit 11, a path set calculation unit 12, and an edge-disjoint path extraction unit 13. The storage unit 11 stores a graph and at least one pair of vertices given for a network represented by vertices and edges, the graph consisting of a set of vertices and a set of edges, the pair of vertices consisting of two vertices included in the set of vertices. The path set calculation unit 12 calculates, for each of the pairs of vertices stored in the storage unit 11, a set of paths each connecting the two vertices with at least one edge included in the set of edges, in the frontier-based search. The edge-disjoint path extraction unit 13 calculates a disjoint join for all the sets of paths calculated by the path set calculation unit 12, to extract all edge-disjoint paths included in the graph stored in the storage unit 11.

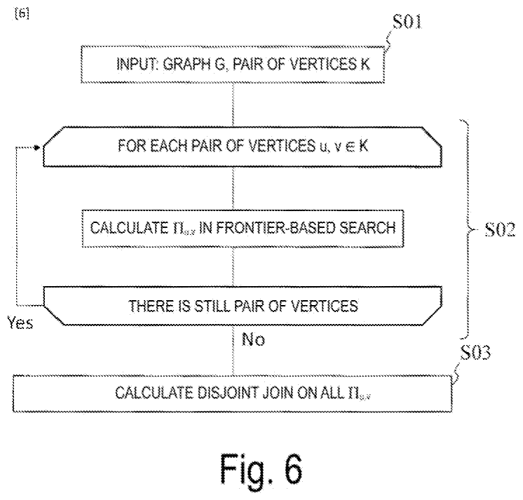

FIG. 6 is a flowchart illustrating a network design evaluation method performed by the present network design evaluation apparatus. The present network design evaluation method includes a condition input step S01 of giving, when a network is represented with vertices and edges, to the storage unit 11, a graph and at least one pair of vertices, the graph consisting of a set of vertices and a set of edges, each of the pairs of vertices consisting of two vertices included in the set of vertices, a path set calculation step S02 of calculating, at the path set calculation unit 12, for each of the pairs of vertices given in the condition input step S01 and stored in the storage unit 11, a set of paths each connecting the two vertices with at least one edge included in the set of edges, in the frontier-based search, and an edge-disjoint path extraction step S03, in which the edge-disjoint path extraction unit 13 calculates a disjoint join for all the sets of paths calculated by the path set calculation unit 12 in the path set calculation step S02, to extract all edge-disjoint paths included in the graph given in the condition input step S01 and stored in the storage unit 11.

Condition Input Step S01

First, for an evaluation target network represented by vertices and edges, a graph G consisting of a set of vertices and a set of edges and at least one pair of vertices K each of the pair consisting of two vertices included in the set of vertices are externally provided to the storage unit 11 such as by an operator or the like.

Path Set Calculation Step S02

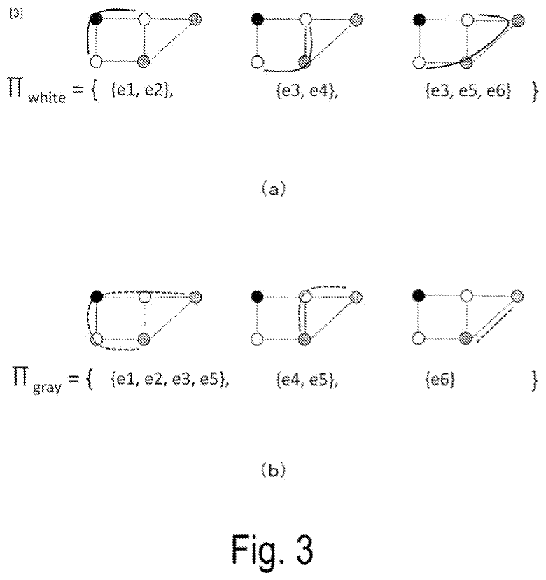

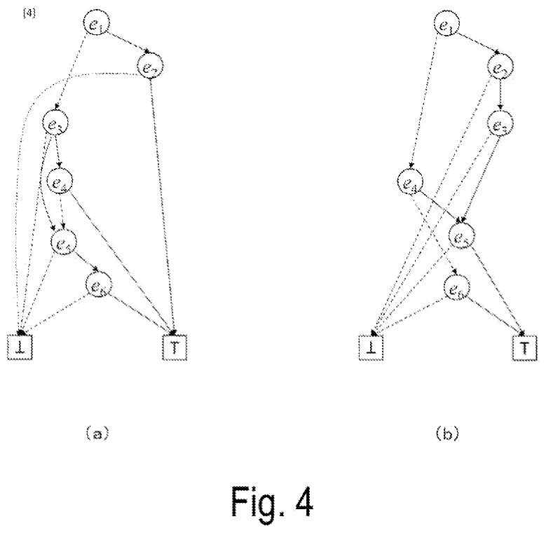

Subsequently, the path set calculation unit 12 finds, for each of the pairs of vertices K, all paths in the frontier-based search described in NPL2. As an example, FIG. 3 illustrates three paths each connecting white vertices and three paths each connecting gray vertices. In the present embodiment, a path is represented as a “set of edges”. Paths found for each vertex are referred to as a “set of paths Π”. FIG. 3 illustrates Π_{white} for white vertices and Π_{gray} for gray vertices. These sets of paths Π are represented as ZDDs in FIG. 4 (see NPL1 for the notation of ZDD).

Edge-Disjoint Path Extraction Step S03

Further, the edge-disjoint path extraction unit 13 joins the sets of paths to provide edge-disjoint paths. In a case that two sets of paths Π₁ and Π₂ are present, it is only required to perform the following disjoint join calculation, to obtain paths P∈Π₁ and P [symbol] Π₂ that do not have common elements.

$$\begin{matrix}[ Math . 1 ] & \\ {\prod }_{1} {\prod }_{2} = \{ P ⋃ {P}^{′} : P ∈ {\prod }_{1} , {P}^{′} ∈ {\prod }_{2} , P ⋂ {P}^{′} = ∅ \} & ( 1 )\end{matrix}$$

Here, [symbol] denotes a Disjoint Join operation.

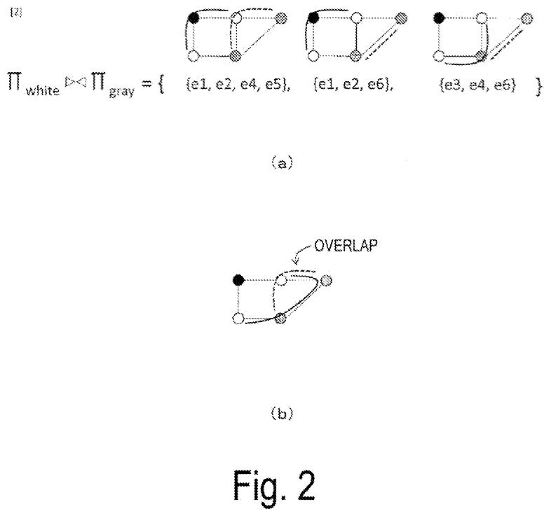

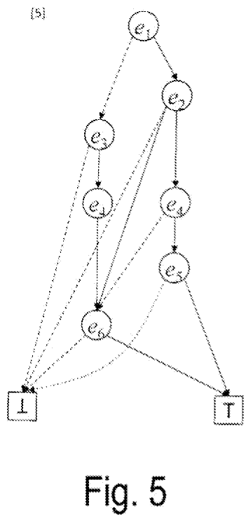

The execution of this calculation utilizes the ZDD algorithm proposed in NPL3. The edge-disjoint extraction unit extracts all the edge-disjoint paths illustrated in FIG. 2, as a result of this calculation, and represents the extracted edge-disjoint paths as a ZDD in FIG. 5 to output.

### Effects of the Invention

According to the network design evaluation method of the present invention, it is possible to represent constraints of edge-disjoint paths as a ZDD. With this, it can be expected that discrete mathematical programming, such as combinatorial optimization and constraint satisfaction problems, is efficiently solved.

### REFERENCE SIGNS LIST

11: Storage unit
12: Path set calculation unit
13: Edge-disjoint path extraction unit

1. A network design evaluation method comprising:
inputting a condition, when a network is represented by vertices and edges, giving a graph and at least one pair of vertices, the graph consisting of a set of vertices and a set of edges, each of the pairs of vertices consisting of two vertices included in the set of vertices;
calculating a path set, for each of the pairs of vertices given in the condition input step, a set of paths each connecting the two vertices with at least one edge included in the set of edges, in frontier-based search; and
extracting an edge-disjoint path by calculating a disjoint join for all the sets of paths calculated in the path set calculation step, to extract all edge-disjoint paths included in the graph given in the condition input step.

2. A network design evaluation apparatus comprising:
a storage unit configured to store a graph and at least one pair of vertices given for a network represented by vertices and edges, the graph consisting of a set of vertices and a set of edges, each of the pairs of vertices consisting of two vertices included in the set of vertices;
a path set calculation unit configured to calculate, for each of the pairs of vertices stored in the storage unit, a set of paths each connecting the two vertices with at least one edge included in the set of edges, in frontier-based search; and
an edge-disjoint path extraction unit configured to calculate a disjoint join for all the sets of paths calculated by the path set calculation unit, to extract all edge-disjoint paths included in the graph stored in the storage unit.

3. A non-transitory computer-readable storage medium storing a program for causing a computer to execute the network design evaluation method according to claim 1.
